(19) United States
(12) Patent Application Publication
(10) Pub. No.: US 2026/0215133 A1
(43) Pub. Date: Jul. 23, 2026

(54) DISPLAY APPARATUS

(71) Applicant: LG Display Co., Ltd., Seoul (KR)

(72) Inventor: Jiyoon SHIN, Paju-si (KR)

(73) Assignee: LG Display Co., Ltd., Seoul (KR)

(21) Appl. No.: 19/443,513

(22) Filed: Jan. 8, 2026

(30) Foreign Application Priority Data
Jan. 22, 2025 (KR) 10-2025-0009447

(51) Int. Cl. H10K 59/80; H10K 59/131

(52) U.S. Cl. CPC H10K 59/873; H10K 59/131; H10K 59/8791

(57) ABSTRACT

According to embodiments of the present specification, there is provided a display apparatus including a display panel including an active area including a plurality of light-emitting elements and a non-active area disposed outside the active area, a polarizing plate disposed on the display panel, an adhesive layer coupling the display panel to the polarizing plate, and a middle frame disposed on a perimeter of the polarizing plate and a perimeter of the display panel, in which the display panel includes a cover layer disposed on an uppermost portion of the active area and in contact with the adhesive layer, and a crack prevention layer disposed between the adhesive layer and the cover layer at an outer edge of the non-active area and in contact with the adhesive layer and the middle frame.

### CROSS REFERENCE TO RELATED APPLICATION

The present application claims priority to Korean Patent Application No. 10-2025-0009447, filed Jan. 22, 2025, the entire contents of which is incorporated herein for all purposes by this reference.

### BACKGROUND

The present specification relates to a display apparatus.

Display apparatuses are applied to various electronic devices such as TVs, mobile phones, notebooks, tablets, etc.

Examples of display apparatuses include organic light-emitting diode (OLED) display apparatuses that emit light by itself, liquid crystal display (LCD) devices that require a separate light source, etc.

A bezel area of the display apparatus is a factor that reduces aesthetics and immersion by being recognized by a user. Recently, narrow bezel display apparatuses that reduce the bezel area in which an image of the display apparatus is not displayed are in the spotlight.

### SUMMARY

In recent years, with the application of a flexible substrate to a display panel, research and development have been conducted to reduce a bezel area of a display apparatus perceived by a user by bending a bending area of a non-active area of a display panel to hide a pad area of the non-active area below an active area.

In addition, a new structure in which a middle frame formed of a resin is disposed around a display panel to protect the display panel from external environments and shocks is being attempted.

In order to improve outdoor visibility of the display apparatus, a polarizer may be attached onto the display panel by an adhesive layer. When the display apparatus is exposed to thermal shock environments, that is, when alternately exposed to high- and low-temperature environments, the polarizer and the middle frame can have different thermal contraction and expansion behaviors. For example, the polarizer can contract under the high-temperature environment, and the middle frame can contract under the low-temperature environment. In the low-temperature environment, the elastic modulus of the adhesive layer can increase, and a contraction force of the middle frame can act as tensile stress on an outer edge of the display panel through the adhesive layer. Accordingly, cracks can occur in an uppermost layer of the display panel, which is bonded to the adhesive layer.

The cracks that occur in the uppermost layer can propagate internally, leading to cracks in lower layers including an encapsulation layer. Due to the penetration of moisture through the cracks, light-emitting elements in the display panel can be degraded, and dark spot defects can occur.

Accordingly, embodiments of the present disclosure are directed to a display apparatus that substantially obviates one or more of the problems due to limitations and disadvantages of the related art.

An aspect of the present disclosure is to provide a display apparatus in which tensile stress applied to an uppermost layer of a display panel can be reduced, thereby preventing the occurrence of cracks in the uppermost layer.

Another aspect of the present disclosure is to provide a display apparatus in which production energy required for production can be reduced and greenhouse gas emissions can be reduced.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a display panel including an active area including a plurality of light-emitting elements and a non-active area disposed outside the active area, a polarizing plate disposed on the display panel, an adhesive layer coupling the display panel to the polarizing plate, and a middle frame disposed on a perimeter of the polarizing plate and a perimeter of the display panel, wherein the display panel includes a cover layer disposed on an uppermost portion of the active area and in contact with the adhesive layer, and a crack prevention layer disposed between the adhesive layer and the cover layer at an outer edge of the non-active area and in contact with the adhesive layer and the middle frame.

In another aspect, a display apparatus comprises a display panel including an active area including a plurality of light-emitting elements and a non-active area disposed outside the active area, in which the display panel includes a cover layer disposed on an uppermost portion of the active area and extending to the non-active area, and a crack prevention layer disposed on an upper surface of the cover layer at an outer edge of the non-active area, and the crack prevention layer may be formed of a polymer material having a higher elastic modulus or tensile strength than a polymer material of the cover layer.

According to the embodiments of the present specification, by arranging the crack prevention layer having a higher elastic modulus or tensile strength than the cover layer on an upper surface of the cover layer, which is the uppermost layer at the outer edge of the display panel, when the display apparatus is exposed to the thermal shock environment, the tensile stress applied to the cover layer, which is the uppermost layer of the display panel, due to the contraction of the middle frame can be reduced, and the occurrence of cracks in the cover layer of the display panel can be prevented. Accordingly, it is possible to prevent dark spot defects in the display panel due to moisture penetration.

According to the embodiments of the present specification, the reliability and lifetime of the display apparatus can be improved, thereby reducing the production energy required to produce the display apparatus and reducing greenhouse gas emissions.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view showing a display apparatus according to one embodiment of the present specification.

FIG. 2 is a cross-sectional view of the display apparatus along line II-II in FIG. 1.

FIG. 3 is an enlarged view of area III in FIG. 2.

FIG. 4 is an enlarged view of area IV in FIG. 2.

FIG. 5 is a cross-sectional view showing the display apparatus according to one embodiment of the present specification.

### DETAILED DESCRIPTION

Advantages and features of the present specification and methods for achieving them will become clear by referencing embodiments described below in detail in conjunction with the accompanying drawings. However, the present specification is not limited to the embodiments disclosed below but will be implemented in various different forms, these embodiments are merely provided to make the disclosure of the present specification complete and fully inform those skilled in the art to which the present specification pertains of the scope of the present specification.

Since shapes, sizes, ratios, angles, numbers, and the like disclosed in the drawings for describing the embodiments of the present specification are exemplary, the present specification is not limited to the shown items. The same reference number denotes the same components throughout the specification. In addition, in describing the present specification, when it is determined that the detailed description of a related known technology may unnecessarily obscure the gist of the present specification, the detailed description thereof will be omitted. When “comprise,” “have,” “consist of,” or the like described herein are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be positioned between the two parts, for example, unless “immediately,” “directly,” or “close to” is used.

When the temporal relationship is described, when the temporal relationship is described using “after,” “subsequently,” “then,” “before,” or the like, it may also include a non-consecutive case unless “immediately” or “directly” is used.

Although terms such as first and second are used to describe various components, these components are not limited by these terms. These terms are only used to distinguish one component from another component. Accordingly, a first component described below may be a second component within the technical spirit of the present specification.

In the description of components of the present specification, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between components that may be connected, coupled, joined, or attached indirectly unless otherwise stated specially.

When a component or a layer is described as “coming into contact with” or “overlapping” another component or layer, the component or the layer may come into direct contact with or directly overlap another component or layer, but it should be understood that still another component may be interposed between components that may come into indirect contact with and indirectly overlap each other unless otherwise stated specially.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, various technological interworking and driving are made possible, and the embodiments may be implemented independently of each other or implemented together in an associated relationship.

Hereinafter, various embodiments of the present specification will be described in detail with reference to the accompanying drawings.

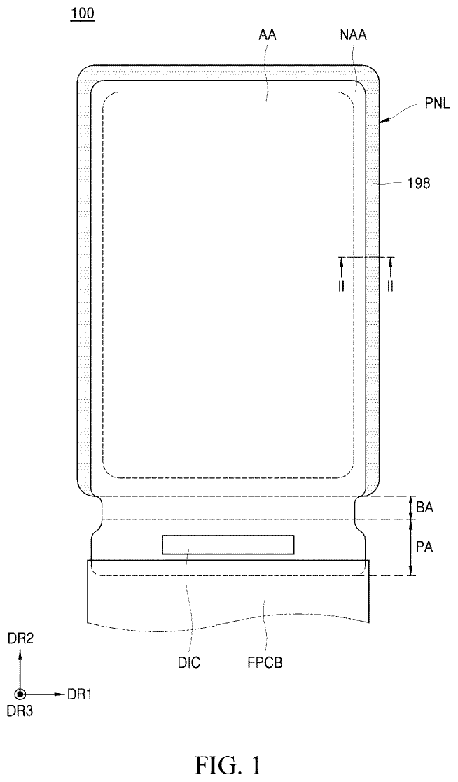

FIG. 1 is a plan view showing a display apparatus according to one embodiment of the present specification.

Referring to FIG. 1, a display apparatus 100 according to one embodiment of the present specification may include a display panel PNL, a data driving unit DIC, a flexible printed circuit board FPCB, etc.

The display panel PNL may include an active area AA and a non-active area NAA. The active area AA and the non-active area NAA may be areas of a substrate of the display panel PNL. The active area AA is an area in which an image is implemented. The active area AA is an area in which a plurality of pixels are disposed. Each pixel may include a plurality of sub-pixels. The non-active area NAA is an area which is located outside the active area AA and in which an image is not implemented. The non-active area NAA is an area in which a gate driver and various signal lines and connection lines are disposed.

The active area AA includes a plurality of data lines and a plurality of gate lines that are disposed to intersect each other. The plurality of gate lines may extend, for example, in a first direction DR1, and the plurality of data lines may extend, for example, in a second direction DR2. The data line transmits a data signal generated by the data driving unit DIC to the sub-pixel, and the gate line transmits gate signals generated by the gate driver to the sub-pixel.

The gate driver may be disposed, for example, in the non-active area NAA located at left and right sides of the active area AA. The gate driver may be disposed directly on the substrate of the display panel PNL using a gate driver in panel (GIP) method.

The non-active area NAA may be disposed to surround the active area AA. The non-active area NAA may be disposed at upper, lower, left, and right sides of the active area AA. The non-active area NAA located below the active area AA includes a pad area PA in which the data driving unit DIC and the flexible printed circuit board FPCB are bonded, and a bending area BA located between the active area AA and the pad area PA. The non-active area NAA located at the upper, left, and right sides of the active area AA may include a crack prevention layer 198. The crack prevention layer 198 may be continuously disposed on the upper, left, and right outer edges of the display panel PNL. Although not shown in FIG. 1, the crack prevention layer 198 may be located outward farther than the gate driver. For example, the gate driver may be located between the active area AA and the crack prevention layer 198.

The data driving unit DIC and the flexible printed circuit board FPCB may be bonded to the pad area PA by an anisotropic conductive film. For example, a timing controller, a power supply, a touch driver, and the like may be mounted on the flexible printed circuit board FPCB.

The bending area BA of the display panel PNL may be bent at a predetermined curvature. As the bending area BA of the display panel PNL is bent, the pad area PA of the non-active area NAA may be located below the active area AA. Accordingly, a lower bezel area of the display apparatus recognized from a front surface of the display apparatus can be reduced.

A touch sensor may be disposed in the active area AA. The touch sensor may include a first touch electrode line extending in the first direction DR1 and a second touch electrode line extending in the second direction DR2. The first touch electrode line and the second touch electrode line may be connected to the flexible printed circuit board FPCB via touch routing lines disposed in the non-active area NAA.

The gate driver may be connected to the flexible printed circuit board FPCB via gate routing lines and the like disposed in the non-active area NAA.

A polarizing layer and a cover member may be disposed on the display panel PNL.

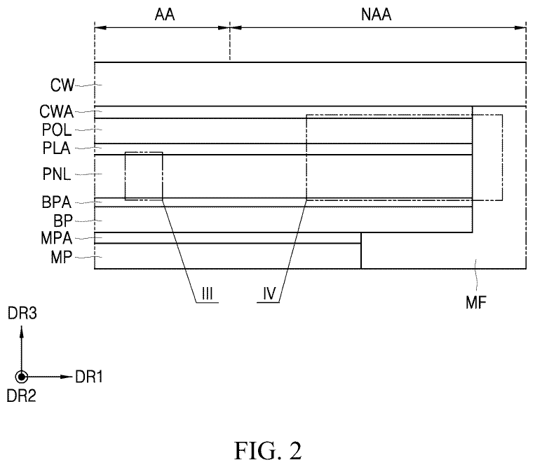

FIG. 2 is a cross-sectional view of the display apparatus along line II-II in FIG. 1.

Referring to FIG. 2, a display apparatus 100 according to one embodiment of the present specification may include the display panel PNL, a polarizing plate POL, a cover member CW, a back plate BP, a support plate MP, and a middle frame MF.

The cover member CW may be attached to an upper surface of the polarizing plate POL by a cover member adhesive layer CWA. A black matrix may be disposed on a lower edge of the cover member CW. The black matrix may be disposed on the non-active area NAA of the display panel PNL, thereby preventing various lines in the non-active area NAA from being visible by a user. The cover member CW may be formed of a glass or plastic material. The cover member adhesive layer CWA may be a transparent adhesive layer that allows light to pass therethrough.

The polarizing plate POL may be attached to an upper surface of the display panel PNL by a polarizing plate adhesive layer PLA. The polarizing plate POL is a circular polarizing plate and can improve the outdoor visibility of the display apparatus by preventing internal reflection due to external light. The polarizing plate POL may be omitted depending on the configuration of the display panel PNL. The polarizing plate adhesive layer PLA may be a transparent adhesive layer that allows light to pass therethrough.

The back plate BP may be located below the active area AA and the non-active area NAA of the display panel PNL. The back plate BP may support the active area AA and the non-active area NAA of the display panel PNL and may be attached to a lower surface of the display panel PNL by a back plate adhesive layer BPA.

The support plate MP may support the active area AA and the non-active area NAA of the display panel PNL together with the back plate BP and may be attached to the lower surface of the back plate BP by a support plate adhesive layer MPA. The support plate MP may include a metal or plastic material. The support plate MP may, for example, at least one of stainless steel (SUS), polycarbonate (PC), polyimide (PI), polyethylene naphthalate (PEN), and polyethylene terephthalate (PET).

The middle frame MF may be disposed along an edge of the cover member CW. The middle frame MF may support the edge of the cover member CW. The middle frame MF may be in contact with the black matrix of the cover member CW. In an embodiment, the middle frame MF may be only disposed in the non-active area NAA.

The middle frame MF may be disposed on a perimeter of the polarizing plate POL and a perimeter of the display panel PNL. The middle frame MF may surround side surfaces of the display panel PNL, side surfaces of the polarizing plate POL, side surfaces of the back plate BP, and side surfaces of the support plate MP. The middle frame MF may be in contact with the side surfaces of the display panel PNL, the side surfaces of the polarizing plate POL, the side surfaces of the back plate BP, and the side surfaces of the support plate MP. The middle frame MF may be in contact with the cover member adhesive layer CWA, the polarizing plate adhesive layer PLA, the back plate adhesive layer BPA, and the support plate adhesive layer MPA. The middle frame MF may be formed of, for example, a photocurable resin.

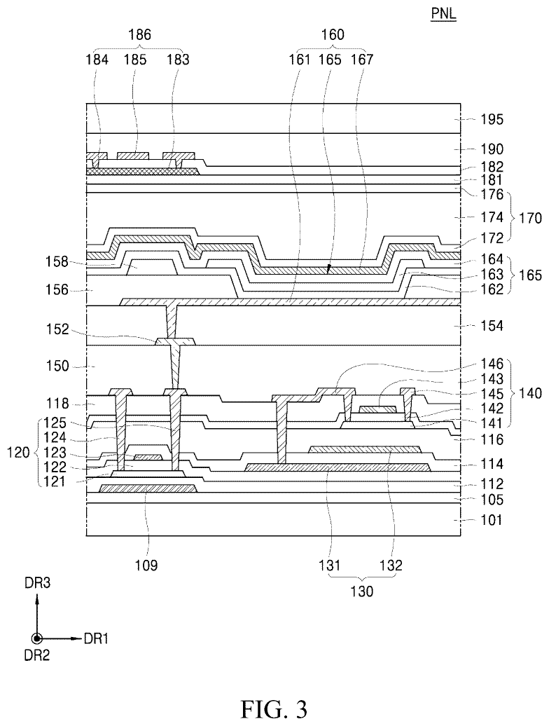

FIG. 3 is an enlarged view of area III in FIG. 2. FIG. 3 is a schematic view showing sub-pixels of a display panel of a display apparatus according to an embodiment of the present specification.

Referring to FIG. 3, the display panel PNL of the display apparatus according to an embodiment of the present specification may include a substrate 101, a first thin film transistor 120, a storage capacitor 130, a second thin film transistor 140, a light-emitting element 160, and a touch sensor 186.

The substrate 101 may include an insulation material. The substrate 101 may include a flexible polymer material. The substrate 101 may have a multilayer structure. For example, the substrate 101 may include a lower substrate layer, an upper substrate layer, and an intermediate layer disposed between the lower and upper substrate layers. For example, the lower and upper substrate layers may be formed of a polyimide-based polymer material. For example, the intermediate layer may be formed of an inorganic insulation material such as silicon oxide, silicon nitride, or silicon oxynitride. The substrate 101 may be a flexible substrate.

The first buffer layer 105 may be disposed on the substrate 101. The first buffer layer 105 may be disposed over the entire active area AA of the substrate 101. The first buffer layer 105 may include an insulation material. For example, the first buffer layer 105 may include an inorganic insulation material such as silicon oxide, silicon nitride, or silicon oxynitride. The first buffer layer 105 may have a multilayer structure.

A light-shielding layer 109 may be disposed on the first buffer layer 105. The light-shielding layer 109 may include a metal material. For example, the light-shielding layer 109 may include a metal material such as aluminum (Al), chromium (Cr), copper (Cu), titanium (Ti), molybdenum (Mo), or tungsten (W).

A second buffer layer 112 covering the light-shielding layer 109 may be disposed on the first buffer layer 105. The second buffer layer 112 may include an insulation material. For example, the second buffer layer 112 may include an inorganic insulation material such as silicon oxide, silicon nitride, or silicon oxynitride. The second buffer layer 112 may have a multilayer structure.

A driving circuit may be positioned in each sub-pixel. The driving circuit may generate a driving current provided to the light-emitting element. The driving circuit may be electrically connected to signal lines. For example, the signal lines may include gate lines that apply gate signals, data lines that apply data signals, and power supply lines that supply power voltages. For example, the driving circuit may include the first thin film transistor 120, the second thin film transistor 140, and the storage capacitor 130.

The first thin film transistor 120 may be electrically connected to the light-emitting element 160. The first thin film transistor 120 may include a first semiconductor pattern 121, a first gate insulating layer 122, a first gate electrode 123, a first source electrode 124, and a first drain electrode 125. The first semiconductor pattern 121 may be disposed on the second buffer layer 112.

The first semiconductor pattern 121 may include a semiconductor material. For example, the first semiconductor pattern 121 may include a polycrystalline semiconductor material. For example, the first semiconductor pattern 121 may include low temperature poly-silicon (LTPS).

The first gate insulating layer 122 may be positioned on the first semiconductor pattern 121. The first gate insulating layer 122 may extend outward from the first semiconductor pattern 121. For example, the first gate insulating layer 122 may extend along an upper surface of the second buffer layer 112. The first gate insulating layer 122 may include an insulation material. For example, the first gate insulating layer 122 may include an inorganic insulation material such as silicon oxide, silicon nitride, and silicon oxynitride.

The first gate electrode 123 may be positioned on the first gate insulating layer 122. The first gate electrode 123 may include a conductive material. For example, the first gate electrode 123 may include a metal material such as aluminum (Al), chromium (Cr), copper (Cu), titanium (Ti), molybdenum (Mo), and tungsten (W). The first gate electrode 123 may be electrically insulated from the first semiconductor pattern 121 by the first gate insulating layer 122. The first gate electrode 123 may overlap a first channel area of the first semiconductor pattern 121.

A first interlayer insulating layer 114 may be positioned on the first gate electrode 123. The first interlayer insulating layer 114 may extend outward from the first gate electrode 123. The first interlayer insulating layer 114 may extend along an upper surface of the first gate insulating layer 122. The first interlayer insulating layer 114 may include an insulation material. For example, the first interlayer insulating layer 114 may include an inorganic insulation material such as silicon oxide, silicon nitride, and silicon oxynitride.

The first source electrode 124 and the first drain electrode 125 may be electrically connected to the first semiconductor patttern 121.

The storage capacitor 130 may include a first storage electrode 131 and a second storage electrode 132. For example, the first storage electrode 131 may be positioned on the same layer as the first gate electrode 123. For example, the first storage electrode 131 may be formed of the same material as the first gate electrode 123. The first storage electrode 131 may be disposed near the first gate electrode 123 on the first gate insulating layer 122. The second storage electrode 132 may be disposed to overlap the first storage electrode 131 on the first interlayer insulating layer 114.

The first storage electrode 131 and the second storage electrode 132 may include a conductive material. For example, the first storage electrode 131 and the second storage electrode 132 may include a metal material such as aluminum (Al), chromium (Cr), copper (Cu), titanium (Ti), molybdenum (Mo), and tungsten (W).

A separation insulating layer 116 may cover the second storage electrode 132 and may be disposed on the first interlayer insulating layer 114. The separation insulating layer 116 may include an insulation material. For example, the separation insulating layer 116 may include an inorganic insulation material such as silicon oxide, silicon nitride, and silicon oxynitride. For example, the separation insulating layer 116 may have a multilayer structure including silicon oxide and silicon nitride.

The second thin film transistor 140 may be electrically connected to the first thin film transistor 120. For example, the second thin film transistor 140 may include a second semiconductor pattern 141, a second gate insulating layer 142, a second gate electrode 143, a second source electrode 145, and a second drain electrode 146.

The second semiconductor pattern 141 may include a semiconductor material. The second semiconductor pattern 141 may include a different material from the first semiconductor pattern 121. For example, the second semiconductor pattern 141 may include an oxide semiconductor such as IGZO. The second semiconductor pattern 141 may be positioned on a different layer from the first semiconductor pattern 121. The second semiconductor pattern 141 may be located on the separation insulating layer 116. Accordingly, it is possible to prevent damage to the second semiconductor pattern 141 due to a process of forming the first semiconductor pattern 121.

The second gate insulating layer 142 may be disposed on the second semiconductor pattern 141. The second gate insulating layer 142 may extend outward from the second semiconductor pattern 141. For example, the second gate insulating layer 142 may extend along an upper surface of the separation insulating layer 116. The second gate insulating layer 142 may include an insulation material. The second gate insulating layer 142 may include an inorganic insulation material such as silicon oxide, silicon nitride, and silicon oxynitride.

The second gate electrode 143 may be disposed on the second gate insulating layer 142. For example, the second gate electrode 143 may overlap the second channel area of the second semiconductor pattern 141. The second gate electrode 143 may include a conductive material. For example, the second gate electrode 143 may include a metal material such as aluminum (Al), chromium (Cr), copper (Cu), titanium (Ti), molybdenum (Mo), and tungsten (W). For example, the second gate electrode 143 may be formed of the same material as the first gate electrode 123. The second gate electrode 143 may be electrically insulated from the second semiconductor pattern 141 by the second gate insulating layer 142.

A second interlayer insulating layer 118 may be positioned on the second gate electrode 143. The second interlayer insulating layer 118 may extend outward from the second gate electrode 143. The second interlayer insulating layer 118 may extend along an upper surface of the separation insulating layer 116. The second interlayer insulating layer 118 may include an insulation material. For example, the second interlayer insulating layer 118 may include an inorganic insulation material such as silicon oxide, silicon nitride, and silicon oxynitride. For example, the second interlayer insulating layer 118 may have a multilayer structure including silicon oxide and silicon nitride.

The first source electrode 124, the first drain electrode 125, the second source electrode 145, and the second drain electrode 146 may be disposed on the second interlayer insulating layer 118. The first source electrode 124, the first drain electrode 125, the second source electrode 145, and the second drain electrode 146 may include a conductive material. For example, the first source electrode 124, the first drain electrode 125, the second source electrode 145, and the second drain electrode 146 may include a metal material such as aluminum (Al), chromium (Cr), copper (Cu), titanium (Ti), molybdenum (Mo), or tungsten (W). For example, the first source electrode 124, the first drain electrode 125, the second source electrode 145, and the second drain electrode 146 may have a multilayer structure of titanium (Ti)/aluminum (Al)/titanium (Ti).

The first source electrode 124 and the first drain electrode 125 may be electrically connected to the first semiconductor pattern 121. For example, the first source electrode 124 and the first drain electrode 125 may be in direct contact with the first semiconductor pattern 121 through contact holes passing through the second interlayer insulating layer 118, the second gate insulating layer 142, the separation insulating layer 116, the first interlayer insulating layer 114, and the first gate insulating layer 122.

The second source electrode 145 and the second drain electrode 146 may be electrically connected to the second semiconductor pattern 141. For example, the second source electrode 145 and the second drain electrode 146 may be in direct contact with the second semiconductor pattern 141 through contact holes passing through the second interlayer insulating layer 118 and the second gate insulating layer 142.

The second thin film transistor 140 may be disposed on the storage capacitor 130. For example, the second semiconductor pattern 141 of the second thin film transistor 140 may overlap the storage capacitor 130. Light passing through the substrate 101 and traveling toward the second semiconductor pattern 141 may be blocked by the storage capacitor 130. Accordingly, a change in the characteristics of the second thin film transistor 140 due to external light can be prevented. The storage capacitor 130 may be electrically connected to the second drain electrode 146 of the second thin film transistor 140. For example, the second drain electrode 146 may be in direct contact with the first storage electrode 131 through a contact hole penetrating the second interlayer insulating layer 118, the second gate insulating layer 142, the separation insulating layer 116, and the first interlayer insulating layer 114.

The light-emitting element 160 may be disposed on the driving circuit. For example, the first thin film transistor 120, the second thin film transistor 140, and the storage capacitor 130 of each sub-pixel may be positioned between the substrate 101 and the light-emitting element 160.

A first planarization layer 150 and a second planarization layer 154 may be sequentially stacked between the driving circuit and the light-emitting element 160. The first planarization layer 150 and the second planarization layer 154 may cover a step caused by the driving circuit to provide a flat surface. For example, the first planarization layer 150 and the second planarization layer 154 may include an organic insulation material.

A pixel contact electrode 152 may be disposed on the first planarization layer 150. The light-emitting element 160 may be disposed on the second planarization layer 154. The light-emitting element 160 may include a first electrode 161, a light-emitting layer 165, and a second electrode 167. The light-emitting element 160 may be electrically connected to the first drain electrode 125 of the first thin film transistor 120 through the pixel contact electrode 152. The pixel contact electrode 152 may include a conductive material. For example, the pixel contact electrode 152 may include a metal material such as aluminum (Al), chromium (Cr), copper (Cu), titanium (Ti), molybdenum (Mo), or tungsten (W). For example, the pixel contact electrode 152 may have a multilayer structure of titanium (Ti)/aluminum (Al)/titanium (Ti).

A bank layer 156 may be disposed on the second planarization layer 154. The bank layer 156 may include an organic insulation material. For example, the bank layer 156 may be formed of a photosensitive acryl-based or polyimide-based polymer. The bank layer 156 may cover an edge of the first electrode 161. The bank layer 156 may have an opening that exposes a part of the first electrode 161. The light-emitting layer 165 and the second electrode 167 of the light-emitting element 160 may be stacked on a part of the first electrode 161 exposed by the bank layer 156. A light-emitting area may be defined by the part of the first electrode 161 exposed by the opening of the bank layer 156. The first electrode 161 may include a conductive material. The first electrode 161 may have high reflectivity. For example, the first electrode 161 may include a metal material such as aluminum (Al) or silver (Ag). The first electrode 161 may have a multilayered structure. For example, the first electrode 161 may have a structure in which a metal such as aluminum (Al) or silver (Ag) is disposed between transparent conductive materials such as ITO and IZO.

The light-emitting layer 165 may extend onto the bank layer 156. The light-emitting layer 165 may include a light-emitting material layer 163. For example, the light-emitting material layer 163 may include an organic light-emitting material. The light-emitting layer 165 may have a multilayered structure. For example, the light-emitting layer 165 may include at least one of a first light-emitting common layer 162 positioned between the first electrode 161 and the light-emitting material layer 163 and a second light-emitting common layer 164 positioned between the light-emitting material layer 163 and the second electrode 167. For example, the first light-emitting common layer 162 may include at least one of a hole injection layer (HIL) and a hole transport layer (HTL). The second light-emitting common layer 164 may include at least one of an electron transport layer (ETL) and an electron injection layer (EIL).

For example, when the sub-pixels of each pixel emit light of different colors, the light-emitting material layer 163 of each sub-pixel may be separated from the light-emitting material layer 163 of an adjacent sub-pixel. The light-emitting material layer 163 of each sub-pixel may be formed separately using a fine metal mask (FMM). An end portion of the light-emitting material layer 163 may be positioned on the bank layer 156.

For example, a spacer 158 may be disposed on the bank layer 156. The spacer 158 can prevent damage to the bank layer 156 and the light-emitting material layer 163 through contact with the FMM. For example, the spacer 158 may be formed of a photosensitive acryl-based or polyimide-based polymer. The bank layer 156 and the spacer 158 may be formed simultaneously by a single photolithography process, but are not limited thereto. The bank layer 156 and the spacer 158 may be formed by separate processes, respectively.

The first light-emitting common layer 162 and the second light-emitting common layer 164 of the light-emitting layer 165 may extend along a surface of the bank layer 156. The first light-emitting common layer 162 and the second light-emitting common layer 164 of the light-emitting layer 165 may cover an upper surface and side surfaces of the spacer 158. For example, the first light-emitting common layer 162 and the second light-emitting common layer 164 may be disposed in common in adjacent sub-pixels. For example, each of the first light-emitting common layer 162 and the second light-emitting common layer 164 may be disposed in common in all pixels in the active area AA.

The second electrode 167 may be disposed in common in adjacent sub-pixels. For example, the second electrode 167 may be disposed in common in all pixels in the active area AA. The second electrode 167 may include a conductive material. For example, the second electrode 167 may be a transparent electrode formed of a transparent conductive material such as ITO and IZO.

An encapsulation part 170 may be positioned on the light-emitting element 160. The encapsulation part 170 can prevent damage to the light-emitting elements 160 due to an external impact and moisture. The encapsulation part 170 may have a multilayered structure. For example, the encapsulation part 170 may include a first encapsulation layer 172, a second encapsulation layer 174, and a third encapsulation layer 176 that are sequentially stacked. For example, the first encapsulation layer 172 and the third encapsulation layer 176 may include an inorganic insulation material, and the second encapsulation layer 174 may include an organic insulation material. The encapsulation part 170 may extend outward from the active area AA.

The touch sensor 186 may be disposed on the encapsulation part 170. The touch sensor 186 may include a bridge electrode 183, a first touch electrode 184, and a second touch electrode 185. The bridge electrode 183, the first touch electrode 184, and the second touch electrode 185 may be disposed at a location overlapping the bank layer 156. Light emitted from each light-emitting element 160 may not be blocked by the bridge electrode 183, the first touch electrode 184, and the second touch electrode 185.

A touch buffer layer 181 may be disposed between the encapsulation part 170 and the touch sensor 186. The touch buffer layer 181 can prevent the encapsulation part 170 and the light-emitting element 160 from being damaged during the process of forming the first touch electrode 184, the bridge electrode 183, and the second touch electrode 185. For example, an upper surface of the encapsulation part 170 may be covered by the touch buffer layer 181. For example, the touch buffer layer 181 may extend to the non-active area NAA. The touch buffer layer 181 may include an insulation material. For example, the touch buffer layer 181 may include an inorganic insulation material such as silicon oxide, silicon nitride, and silicon oxynitride.

The bridge electrode 183 may be disposed on the touch buffer layer 181. A touch insulating layer 182 may be disposed on the bridge electrode 183. The touch insulating layer 182 may extend along an upper surface of the touch buffer layer 181. For example, the touch insulating layer 182 may extend to the non-active area NAA. For example, the touch insulating layer 182 may include an inorganic insulation material such as silicon oxide, silicon nitride, and silicon oxynitride.

The first touch electrodes 184 and the second touch electrodes 185 may be disposed on the touch insulating layer 182. The bridge electrode 183 may electrically connect adjacent first touch electrodes 184. The adjacent first touch electrodes 184 may be connected to the bridge electrode 183 through contact holes passing through the touch insulating layer 182. The bridge electrode 183 and the first touch electrode 184 may form a first touch electrode line. The second touch electrode 185 may form a second touch electrode line.

The bridge electrode 183, the first touch electrode 184, and the second touch electrode 185 may include a conductive material. For example, the bridge electrode 183, the first touch electrode 184, and the second touch electrode 185 may include a metal material such as aluminum (Al), chromium (Cr), copper (Cu), titanium (Ti), molybdenum (Mo), or tungsten (W). For example, the bridge electrode 183, the first touch electrode 184, and the second touch electrode 185 may have a multilayer structure of titanium (Ti)/aluminum (Al)/titanium (Ti).

A touch protective layer 190 may be disposed on the touch sensor 186. The touch protective layer 190 can prevent damage to the touch sensor 186 due to external impacts and moisture. The touch protective layer 190 may extend along an upper surface of the touch insulating layer 182. The touch protective layer 190 may extend to the non-active area NAA. The touch protective layer 190 may include an insulation material. For example, the touch protective layer 190 may include an organic insulation material. For example, the touch protective layer 190 may be formed of a photosensitive acryl-based polymer.

A cover layer 195 may be disposed on the touch protective layer 190. The cover layer 195 may extend along an upper surface of the touch protective layer 190. The cover layer 195 may extend to the non-active area NAA. For example, the cover layer 195 may include an organic insulation material. For example, the cover layer 195 may be formed of an epoxy-based polymer.

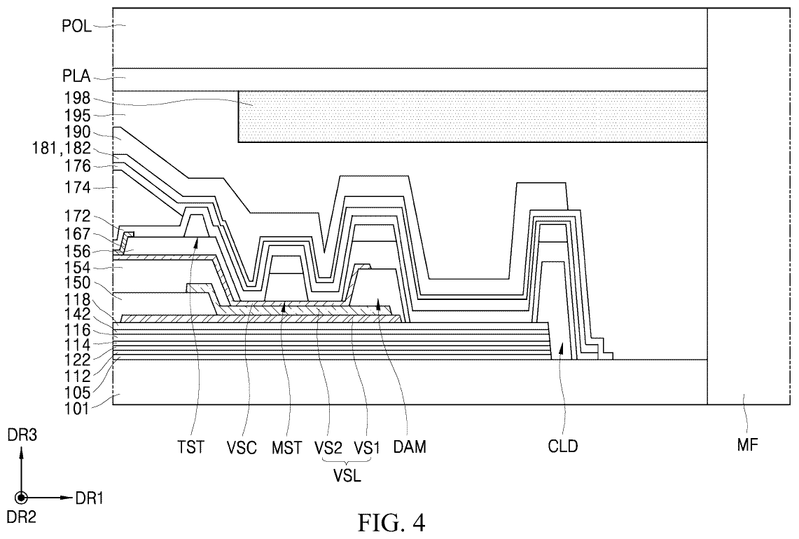

FIG. 4 is an enlarged view of area IV in FIG. 2.

Referring to FIG. 4, the display apparatus according to one embodiment of the present specification may include the display panel PNL, the polarizing plate adhesive layer PLA, the polarizing plate POL, and the middle frame MF.

In the non-active area NAA of the display panel PNL, inorganic insulating layers, that is, the first buffer layer 105, the second buffer layer 112, the first gate insulating layer 122, the first interlayer insulating layer 114, the separation insulating layer 116, the second gate insulating layer 142, and the second interlayer insulating layer 118, may be sequentially stacked on the substrate 101.

Cracks can easily occur in the inorganic insulating layers disposed on the edge of the substrate 101 due to external impacts or a laser trimming process. The generated cracks may propagate to the active area AA, and moisture or oxygen flowing into the active area AA along the cracks can deteriorate the light-emitting element 160.

In the present embodiment, in order to prevent cracks from occurring and propagating due to external impacts or a laser trimming process, end portions of the first buffer layer 105, the second buffer layer 112, the first gate insulating layer 122, the first interlayer insulating layer 114, the separation insulating layer 116, the second gate insulating layer 142, and the second interlayer insulating layer 118, which are formed of an inorganic insulating material, may be spaced apart from the edge of the substrate 101.

A low-potential power line VSL may be disposed on the second interlayer insulating layer 118. The low-potential power line VSL may be disposed to have a predetermined width on an upper surface of the second interlayer insulating layer 118. The low-potential power line VSL may include a first low-potential power line VS1 and a second low-potential power line VS2. The second low-potential power line VS2 may be directly disposed on an upper surface of the first low-potential power line VS1.

The first low-potential power line VS1 may be formed of the same material as the second source electrode 145 and the second drain electrode 146 of the second thin film transistor 140. The second low-potential power line VS2 may be formed of the same material as the pixel contact electrode 152.

The first planarization layer 150 may be disposed on the second interlayer insulating layer 118. The first planarization layer 150 may cover a portion of the first low-potential power line VS1.

The second low-potential power line VS2 may also be disposed on a portion of an upper surface and a side surface of the first planarization layer 150.

The second planarization layer 154 may be disposed on the first planarization layer 150. The second planarization layer 154 may cover a portion of the second low-potential power line VS2.

A low-potential power connection electrode VSC may be disposed on the second planarization layer 154. The low-potential power connection electrode VSC may be disposed on an entire of an upper surface and a side surface of the second planarization layer 154. The low-potential power connection electrode VSC may extend outward farther than an end of the second planarization layer 154 and may be in contact with the second low-potential power line VS2. The low-potential power connection electrode VSC may be formed of the same material as the first electrode 161 of the light-emitting element 160 and formed simultaneously with the first electrode 161.

The bank layer 156 may be disposed on the low-potential power connection electrode VSC. The bank layer 156 may cover a portion of the low-potential power connection electrode VSC.

A top stopper TST may be disposed on the bank layer 156. The top stopper TST may be formed of the same material as the spacer 158 and formed simultaneously with the spacer 158.

The second electrode 167 of the light-emitting element 160 may be connected to the low-potential power connection electrode VSC through the bank layer 156. The second electrode 167 of the light-emitting element 160 may be connected to the low-potential power line VSL through the low-potential power connection electrode VSC in the non-active area NAA.

A mid-stopper MST may be disposed to have a predetermined width on the low-potential power line VSL. The mid-stopper MST may be disposed outside the top stopper TST. The mid-stopper MST may include a first stopper layer and a second stopper layer sequentially stacked on the low-potential power line VSL. For example, the first stopper layer may be formed of the same material as the bank layer 156 and formed simultaneously with the bank layer 156. For example, the second stopper layer may be formed of the same material as the spacer 158 and formed simultaneously with the spacer 158.

A dam DAM covering an edge of the low-potential power line VSL may be disposed to have a predetermined width on the second interlayer insulating layer 118. The dam DAM may be disposed outside the mid-stopper MST. The dam DAM may include three dam layers. For example, a first dam layer may be formed of the same material as the second planarization layer 154 and formed simultaneously with the second planarization layer 154. For example, a second dam layer may be formed of the same material as the bank layer 156 and formed simultaneously with the bank layer 156. For example, a third dam layer may be formed of the same material as the spacer 158 and may be formed simultaneously with the spacer 158.

A cladding part CLD may be disposed to have a predetermined width outside the dam DAM. The cladding part CLD may cover end portions of the first buffer layer 105, the second buffer layer 112, the first gate insulating layer 122, the first interlayer insulating layer 114, the separation insulating layer 116, the second gate insulating layer 142, and the second interlayer insulating layer 118. The cladding part CLD may include three cladding layers. For example, a first cladding layer may be formed of the same material as the second planarization layer 154 and formed simultaneously with the second planarization layer 154. For example, a second cladding layer may be formed of the same material as the bank layer 156 and formed simultaneously with the bank layer 156. For example, a third cladding layer may be formed of the same material as the spacer 158 and formed simultaneously with the spacer 158.

The first encapsulation layer 172, the second encapsulation layer 174, and the third encapsulation layer 176 may be disposed on the bank layer 156. The first encapsulation layer 172 may extend to the edge of the substrate 101 and cover the bank layer 156, the top stopper TST, the mid-stopper MST, the dam DAM, and the cladding part CLD.

The top stopper TST, the mid-stopper MST, and the dam DAM may each be disposed in a closed loop form. The top stopper TST, the mid-stopper MST, and the dam DAM may limit a flow of a fluid organic insulation material when the second encapsulation layer 174 is formed. Accordingly, the second encapsulation layer 174 may be disposed within only a portion of the substrate 101. For example, the second encapsulation layer 174 may be disposed inside the top stopper TST.

The third encapsulation layer 176 may come into direct contact with the first encapsulation layer 172 outside the second encapsulation layer 174. The third encapsulation layer 176 may extend toward the edge of the substrate 101 and extend in the same direction as the first encapsulation layer 172.

In order to prevent cracks from occurring and propagating due to external impacts or the laser trimming process, end portions of the first encapsulation layer 172 and the third encapsulation layer 176, which are formed of an inorganic insulation material, may be spaced apart from the edge of the substrate 101.

The touch buffer layer 181 and the touch insulating layer 182 may be disposed on the third encapsulation layer 176. The touch buffer layer 181 and the touch insulating layer 182 may cover the end portions of the first encapsulation layer 172 and the third encapsulation layer 176. In order to prevent cracks from occurring and propagating due to external impacts or the laser trimming process, the end portions of the touch buffer layer 181 and the touch insulating layer 182, which are formed of an inorganic insulation material, may be spaced apart from the edge of the substrate 101.

The touch protective layer 190 may be disposed on the touch insulating layer 182. For example, an end portion of the touch protective layer 190 may be located on the cladding part CLD.

The cover layer 195 may be disposed on the touch protective layer 190 and may extend to the edge of the substrate 101. The cover layer 195 may be disposed directly on an upper surface of the substrate 101 at the outer edge of the substrate 101. For example, the cover layer 195 may include an organic insulation material. For example, the cover layer 195 may be formed of an epoxy-based polymer.

The crack prevention layer 198 may be disposed on an upper surface of the cover layer 195 at the outer edge of the display panel PNL. The crack prevention layer 198 may be disposed between the polarizing plate adhesive layer PLA and the cover layer 195 at the outer edge of the non-active area NAA of the display panel PNL. For example, the crack prevention layer 198 may have a portion that overlaps the low-potential power line VSL. For example, the crack prevention layer 198 may be disposed to overlap the mid-stopper MST, the dam DAM, and the cladding part CLD. An inner end portion of the crack prevention layer 198 may be located inward farther than the mid-stopper MST. For example, the crack prevention layer 198 may be formed of a polymer material having a higher elastic modulus than the cover layer 195. The crack prevention layer 198 may be formed of a polymer material having a higher tensile strength than the cover layer 195. For example, the crack prevention layer 198 may be formed of a polyimide-based polymer.

The polarizing plate adhesive layer PLA may be disposed on the cover layer 195 and the crack prevention layer 198. The polarizing plate POL may be attached to the cover layer 195 and the crack prevention layer 198 by the polarizing plate adhesive layer PLA. The polarizing plate POL, the polarizing plate adhesive layer PLA, the crack prevention layer 198, and the cover layer 195 may be in contact with the middle frame MF.

According to the present embodiment, by arranging the crack prevention layer having a higher elastic modulus or tensile strength than the cover layer on the upper surface of the cover layer, which is the uppermost layer at the outer portion of the display panel, when the display apparatus is exposed to the thermal shock environment, the tensile stress applied to the cover layer, which is the uppermost layer of the display panel, due to the contraction of the middle frame can be reduced, and the occurrence of cracks in the cover layer of the display panel can be prevented. Accordingly, it is possible to prevent dark spot defects in the display panel due to moisture penetration.

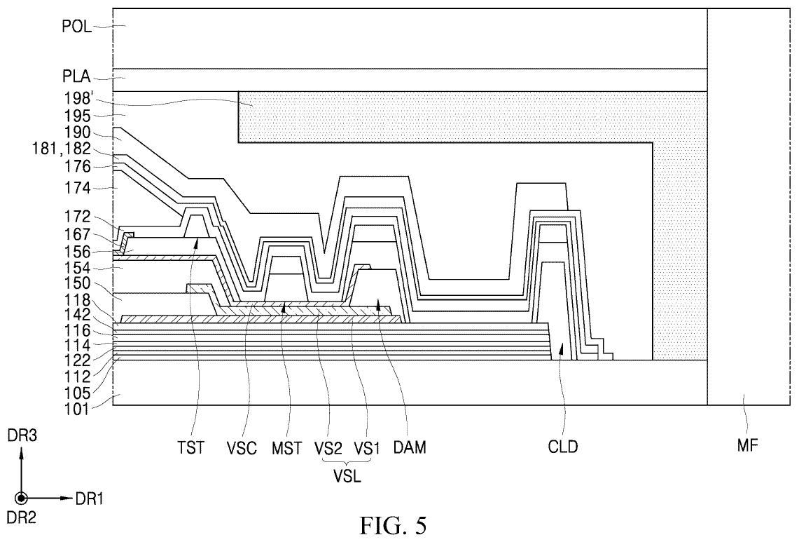

FIG. 5 is a cross-sectional view showing the display apparatus according to one embodiment of the present specification.

Referring to FIG. 5, a crack prevention layer 198′ may be disposed on the upper surface and side surface of the cover layer 195 at the outer edge of the display panel PNL. For example, the crack prevention layer 198′ may have a portion that overlaps the low-potential power line VSL. For example, the crack prevention layer 198′ may be disposed to overlap the mid-stopper MST, the dam DAM, and the cladding part CLD. An inner end portion of the crack prevention layer 198′ may be located inward farther than the mid-stopper MST. The crack prevention layer 198′ may cover the side surface of the cover layer 195 and may be in contact with the substrate 101. For example, the crack prevention layer 198′ may be formed of a polymer material having a higher elastic modulus than the cover layer 195. The crack prevention layer 198′ may be formed of a polymer material having a higher tensile strength than the cover layer 195. For example, the crack prevention layer 198′ may be formed of a polyimide-based polymer. According to the present embodiment, the outer edge of the display panel PNL may be surrounded by the polyimide-based polymer.

In one embodiment, the crack prevention layer 198′ may cover an upper region of the side surface of the cover layer 195.

The polarizing plate adhesive layer PLA may be disposed on the cover layer 195 and the crack prevention layer 198′. The polarizing plate POL may be attached to the cover layer 195 and the crack prevention layer 198′ by the polarizing plate adhesive layer PLA. The polarizing plate POL, the polarizing plate adhesive layer PLA, and the crack prevention layer 198′ may be in contact with the middle frame MF.

According to the present embodiment, by arranging the crack prevention layer having a higher elastic modulus or tensile strength than the cover layer on the upper surface of the cover layer, which is the uppermost layer at the outer portion of the display panel, when the display apparatus is exposed to the thermal shock environment, the tensile stress applied to the cover layer, which is the uppermost layer of the display panel, due to the contraction of the middle frame can be reduced, and the occurrence of cracks in the cover layer of the display panel can be prevented. Accordingly, it is possible to prevent dark spot defects in the display panel due to moisture penetration.

A display apparatus according to various embodiments of the present specification may be described as follows.

According to embodiments of the present specification, there is provided a display apparatus including a display panel including an active area including a plurality of light-emitting elements and a non-active area disposed outside the active area, a polarizing plate disposed on the display panel, an adhesive layer coupling the display panel to the polarizing plate, and a middle frame disposed on a perimeter of the polarizing plate and a perimeter of the display panel, in which the display panel includes a cover layer disposed on an uppermost portion of the active area and in contact with the adhesive layer, and a crack prevention layer disposed between the adhesive layer and the cover layer at an outer edge of the non-active area and in contact with the adhesive layer and the middle frame.

According to some embodiments of the present specification, the crack prevention layer may be formed of a polymer material having a higher elastic modulus than a polymer material of the cover layer.

According to some embodiments of the present specification, the crack prevention layer may be formed of a polymer material having a higher tensile strength than a polymer material of the cover layer.

According to some embodiments of the present specification, the crack prevention layer may be formed of the same polymer material as a polymer material of a substrate of the display panel.

According to some embodiments of the present specification, the crack prevention layer may be disposed on an upper surface and side surface of the cover layer at an outer edge of the non-active area.

According to some embodiments of the present specification, the crack prevention layer may cover the side surface of the cover layer and may be in contact with the substrate of the display panel.

According to some embodiments of the present specification, the display panel may further include a low-potential voltage line disposed in the non-active area, and the crack prevention layer may have a portion overlapping the low-potential voltage line.

According to some embodiments of the present specification, the display panel may further include a mid-stopper disposed on the low-potential voltage line in the non-active area, and an inner end portion of the crack prevention layer may be located inward farther than the mid-stopper.

According to some embodiments of the present specification, the mid frame may be formed of a photocurable resin.

According to embodiments of the present specification, there is provided a display apparatus including a display panel including an active area including a plurality of light-emitting elements and a non-active area disposed outside the active area, in which the display panel includes a cover layer disposed on an uppermost portion of the active area and extending to the non-active area, and a crack prevention layer disposed on an upper surface of the cover layer at an outer edge of the non-active area, and the crack prevention layer may be formed of a polymer material having a higher elastic modulus or tensile strength than a polymer material of the cover layer.

According to some embodiments of the present specification, the crack prevention layer may be formed of the same polymer material as a polymer material of the substrate of the display panel.

According to some embodiments of the present specification, the crack prevention layer may be disposed on an upper surface and side surface of the cover layer at an outer edge of the non-active area.

According to some embodiments of the present specification, the crack prevention layer may cover the side surface of the cover layer and may be in contact with the substrate of the display panel.

According to some embodiments of the present specification, the display panel may further include a low-potential voltage line disposed in the non-active area, and the crack prevention layer may have a portion overlapping the low-potential voltage line.

According to some embodiments of the present specification, the display panel may further include a mid-stopper disposed on the low-potential voltage line in the non-active area, and an inner end portion of the crack prevention layer may be located inward farther than the mid-stopper.

According to the embodiments of the present specification, by arranging the crack prevention layer having a higher elastic modulus or tensile strength than the cover layer on an upper surface of the cover layer, which is the uppermost layer at the outer edge of the display panel, when the display apparatus is exposed to the thermal shock environment, the tensile stress applied to the cover layer, which is the uppermost layer of the display panel, due to the contraction of the middle frame can be reduced, and the occurrence of cracks in the cover layer of the display panel can be prevented. Accordingly, it is possible to prevent dark spot defects in the display panel due to moisture penetration.

According to the embodiments of the present specification, the reliability and lifetime of the display apparatus can be improved, thereby reducing the production energy required to produce the display apparatus and reducing greenhouse gas emissions.

Effects of the present specification are not limited to the above effects, and other effects that are not described will be able to be clearly understood by those skilled in the art based on the above detailed description.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a display panel including an active area including a plurality of light-emitting elements and a non-active area disposed outside the active area;
a polarizing plate disposed on the display panel;
an adhesive layer coupling the display panel to the polarizing plate; and
a middle frame disposed on a perimeter of the polarizing plate and a perimeter of the display panel,
wherein the display panel includes:
a cover layer disposed on an uppermost portion of the active area and in contact with the adhesive layer; and
a crack prevention layer disposed between the adhesive layer and the cover layer at an outer edge of the non-active area and in contact with the adhesive layer and the middle frame.

2. The display apparatus of claim 1, wherein the crack prevention layer is formed of a polymer material having a higher elastic modulus than a polymer material of the cover layer.

3. The display apparatus of claim 1, wherein the crack prevention layer is formed of a polymer material having a higher tensile strength than a polymer material of the cover layer.

4. The display apparatus of claim 1, wherein the crack prevention layer is formed of a same polymer material as the polymer material of a substrate of the display panel.

5. The display apparatus of claim 1, wherein the crack prevention layer is disposed on an upper surface and side surface of the cover layer at an outer edge of the non-active area.

6. The display apparatus of claim 5, wherein the crack prevention layer covers the side surface of the cover layer and is in contact with a substrate of the display panel.

7. The display apparatus of claim 1, wherein the display panel includes a low-potential voltage line disposed in the non-active area, and
the crack prevention layer has a portion overlapping the low-potential voltage line.

8. The display apparatus of claim 7, wherein the display panel further includes a mid-stopper disposed on the low-potential voltage line in the non-active area, and
an inner end portion of the crack prevention layer is located inward farther than the mid-stopper.

9. The display apparatus of claim 1, wherein the middle frame is formed of a photocurable resin.

10. A display apparatus, comprising:
a display panel including an active area including a plurality of light-emitting elements and a non-active area disposed outside the active area,
wherein the display panel includes:
a cover layer disposed on an uppermost portion of the active area and extending to the non-active area; and
a crack prevention layer disposed on an upper surface of the cover layer at an outer edge of the non-active area, and
the crack prevention layer is formed of a polymer material having a higher elastic modulus or tensile strength than a polymer material of the cover layer.

11. The display apparatus of claim 10, wherein the crack prevention layer is formed of the same polymer material as the polymer material of a substrate of the display panel.

12. The display apparatus of claim 10, wherein the crack prevention layer is disposed on an upper surface and side surface of the cover layer at an outer edge of the non-active area.

13. The display apparatus of claim 12, wherein the crack prevention layer covers the side surface of the cover layer and is in contact with a substrate of the display panel.

14. The display apparatus of claim 10, wherein the display panel further includes a low-potential voltage line disposed in the non-active area, and
the crack prevention layer has a portion overlapping the low-potential voltage line.

15. The display apparatus of claim 14, wherein the display panel further includes a mid-stopper disposed on the low-potential voltage line in the non-active area, and
an inner end portion of the crack prevention layer is located inward farther than the mid-stopper.
